(19) United States
(12) Patent Application Publication
(10) Pub. No.: US 2017/0307973 A1
(43) Pub. Date: Oct. 26, 2017

(54) METHOD FOR CONTROLLING THE LEVEL OF DEFECTS IN FILMS OBTAINED WITH BLENDS OF BLOCK COPOLYMERS AND POLYMERS

(71) Applicant: Arkema France, Colombes (FR)

(72) Inventors: Christophe NAVARRO, Bayonne (FR); Celia NICOLET, Sauvagnon (FR); Xavier CHEVALIER, Grenoble (FR)

(73) Assignee: Arkema France, Colombes (FR)

(21) Appl. No.: 15/510,204

(22) PCT Filed: Sep. 9, 2015
(86) PCT No.: PCT/FR2015/052389

§ 371 Date: Mar. 9, 2017

(30) Foreign Application Priority Data
Sep. 10, 2014 (FR) 14.58477

(51) Int. Cl. G03F 7/00; C09D 153/00; C09D 125/14; G03F 1/50; B05D 3/00

(52) U.S. Cl. CPC G03F 7/0002; G03F 1/50; B05D 3/002; C09D 125/14; C09D 153/00

(57) ABSTRACT

The present invention relates to a method for controlling the level of defects in films obtained using a composition comprising a blend of block copolymers and polymers deposited on a surface. The polymers comprise at least one monomer identical to those present in one or other block of the block copolymers.

The present invention relates to a method for controlling the level of defects in films obtained using a composition comprising a blend of block copolymers and polymers deposited on a surface. The polymers comprise at least one monomer identical to those present in one or other block of the block copolymers.

On account of their capacity for nanostructuring, the use of block copolymers in the fields of materials and electronics or optoelectronics is now well known. This new technology allows access to advanced nano-lithographic processes for manufacture of objects and preparation, with resolutions in terms of size of domains ranging from a few nanometres to several tens of nanometres.

It is in particular possible to structure the arrangement of the blocks constituting the copolymers at scales well below 100 nm. Unfortunately it is difficult to obtain films that are free from defects.

Some authors have investigated the possible effect of adding one or more homopolymers to the block copolymer.

In Macromolecules 1991, 24, 6182-6188, Winey K. et al. discuss this effect on lamellar morphologies, in particular the thickness of the lamellae and layers, in a polystyrene-b-polyisoprene system in the presence of homopolystyrene.

In Macromolecules, 1995, 28, 5765-5773, Matsen M. investigates, by SCFT (self-consistent field theory) simulation, the behaviour of blends of block copolymers with a (co)-polymer. These simulations show that addition of a homopolymer has an influence on the final morphology of the blend even as far as stabilization of the hexagonal morphology.

In Macromolecules 1997, 30, 5698-5703, Torikai N. et al., still in the area of lamellar morphologies, present a similar study in which they show the possible effect of the molecular weight of the homopolymer added. The system studied is polystyrene-b-polyvinyl pyridine in the presence of polystyrene or polyvinyl pyridine.

In Adv. Mater. 2004, 16, No. 6, 533-536, Russel et al. demonstrate that addition of polymethyl methacrylate (PMMA) to a polystyrene-b-polymethyl methacrylate (PS-b-PMMA) copolymer, with a size of the polymethyl methacrylate homopolymer slightly greater than that of the polymethyl methacrylate block of the corresponding block copolymer, makes it possible to obtain a perpendicular cylindrical morphology independent of the thickness of the film.

More recently, in Langmuir, 2007, 23, 6404-6410, Kitano H. et al. report preferential perpendicular control of cylindrical domains by adding polystyrene homopolymers to polystyrene-b-polymethyl methacrylate. They suggest that this property derives from the decrease in stress from the hexagonal symmetry on adding polystyrene. The same effect is demonstrated by adding polymethyl methacrylate.

In Soft Matter, 2008, 1454-1466, Up Ahn D. et al. also present a similar discussion, focusing their work on the effect of the molecular weight of the homopolymer added to the block copolymer on the size, stability and periodicity of the cylinders.

Finally, in Macromolecules 2009, 42, 5861-5872, Su-Mi Hur et al. investigate simulations of morphologies derived from blends of block copolymers and a homopolymer. They demonstrate that by adding copolymer it is possible to achieve stable tetragonal symmetry, which is not the case with the pure block copolymer.

Although these studies show an effect of the presence of a polymer (homopolymer or copolymer) on the behaviour of the film obtained, none of these studies gives any indication regarding quantification of the defects, even less regarding the best way of minimizing them. Moreover, no study relates to reducing the defects of distance, of coordination number or improvement of CDU (critical dimension uniformity).

In fact, the nanostructuring of a block copolymer with a surface treated by the method of the invention may take forms such as cylindrical (hexagonal symmetry (“6 mm” primary hexagonal network symmetry) according to the Hermann-Mauguin notation, or tetragonal/quadratic symmetry (“4 mm” primary tetragonal network symmetry)), spherical symmetry (hexagonal symmetry (“6 mm” or “6/mmm” primary hexagonal network symmetry), or tetragonal/quadratic symmetry (“4 mm” primary tetragonal network symmetry), or cubic symmetry (“m⅓m” network symmetry)), lamellar, or gyroid. Preferably, the preferred form assumed by the nanostructuring is of the cylindrical hexagonal type.

The process of self-assembly of the block copolymers on a surface treated according to the invention is governed by thermodynamic laws. When self-assembly leads to morphology of the cylindrical type, each cylinder is surrounded by 6 equidistant adjacent cylinders if there is no defect. Several types of defects may thus be identified. The first type is based on evaluation of the number of neighbours around a cylinder formed by the arrangement of the block copolymer, also called defects of coordination number. If five or seven cylinders surround the cylinder in question, it will be considered that there is a defect of coordination number. The second type of defect considers the average distance between the cylinders surrounding the cylinder in question. [W. Li, F. Qiu, Y. Yang, and A. C. Shi, Macromolecules 43, 2644 (2010); K. Aissou, T. Baron, M. Kogelschatz, and A. Pascale, Macromol. 40, 5054 (2007); R. A. Segalman, H. Yokoyama, and E. J. Kramer, Adv. Matter. 13, 1152 (2003); R. A. Segalman, H. Yokoyama, and E. J. Kramer, Adv. Matter. 13, 1152 (2003)]. When this distance between two neighbours is above two percent of the average distance between two neighbours, it will be considered that there is a defect. To determine these two types of defects, classically the Voronol constructions and the associated Delaunay triangulations are used. After digitization of the image, the centre of each cylinder is identified. The Delaunay triangulation then makes it possible to identify the number of first-order neighbours and calculate the average distance between two neighbours. It is thus possible to determine the number of defects.

This method of counting is described in the article by Tiron et al. (J. Vac. Sci. Technol. B 29(6), 1071-1023, 2011.

A last type of defect concerns the angle of cylinders of the block copolymer deposited on the surface. When the block copolymer is no longer perpendicular to the surface, it will be considered that there is a defect of orientation.

The method of the invention makes it possible to obtain nanostructured assemblies in the form of films with a minimum of defects of orientation, of coordination number or of distance on large single-crystal surfaces.

Finally, the method of the invention allows films to be prepared with an improved parameter of critical dimension uniformity.

Critical dimension uniformity (CDU) in a film of block copolymers having a cylindrical morphology corresponds to uniform size of the diameter of the cylinders. In the ideal case, it is necessary for all the cylinders to have the same diameter, as any variation of this diameter will induce variations of performance (conductivity, characteristics of the transfer curves, thermal power released, resistance, etc.) for the applications considered.

The applicant has found that blends comprising block copolymers and polymers that comprise at least one monomer identical to those present in one or other block of the block copolymers allows a significant decrease in the aforementioned defects accompanied by an optimum with respect to the mass of the polymers blended with the block copolymers and of the ratio of the masses of the polymers and the masses of the block copolymers.

### SUMMARY OF THE INVENTION

The invention relates to a method for controlling the level of defects of orientation, of coordination number or of distance on large single-crystal surfaces with an improvement of CDU of a nanostructured assembly in the form of a film of a blend of block copolymers and polymers, said blend comprising n block copolymers and m polymers that comprise at least one monomer identical to those present in one or other block of the block copolymers, comprising the following steps:
Mixing comprising block copolymers and polymers in a solvent.
Depositing this blend on a surface.
Annealing

### DETAILED DESCRIPTION

“Surface” means a surface which may or may not be flat. “Annealing” means a heating step allowing evaporation of the solvent when it is present, and allowing establishment of the required nanostructuring.

Any block copolymer, regardless of its associated morphology, can be used in the context of the invention, whether it is a diblock, linear or star triblock, linear multiblock, comb or star copolymer. Preferably, they are diblock or triblock copolymers, and more preferably diblock copolymers.

The polymers will either be homopolymers, or random copolymers.

In the context of the invention, it will be possible to blend n block copolymers with m polymers, n being an integer between 1 and 10, inclusive. Preferably, n is between 1 and 5, inclusive, and preferably n is between 1 and 2, inclusive, and more preferably n is equal to 1, m being an integer between 1 and 10, inclusive. Preferably, m is between 1 and 5, inclusive, and preferably m is between 1 and 2, inclusive, and more preferably m is equal to 1.

These block copolymers and polymers can be synthesized by any techniques known by a person skilled in the art, among which we may mention polycondensation, ring-opening polymerization, anionic, cationic or radical polymerization, and said techniques may or may not be controlled, and combined with one another or not. When the copolymers are prepared by radical polymerization, the latter can be controlled by any known technique such as NMP (“Nitroxide Mediated Polymerization”), RAFT (“Reversible Addition and Fragmentation Transfer”), ATRP (“Atom Transfer Radical Polymerization”), INIFERTER (“Initiator-Transfer-Termination”), RITP (“Reverse Iodine Transfer Polymerization”), ITP (“Iodine Transfer Polymerization”).

According to a preferred embodiment of the invention, the block copolymers and the polymers are prepared by controlled radical polymerization, even more particularly by polymerization controlled by nitroxides, in particular N-tert-butyl-1-diethylphosphono-2,2-dimethylpropyl nitroxide.

According to a second preferred embodiment of the invention, the block copolymers and the polymers are prepared by anionic polymerization.

When polymerization is carried out by radical polymerization, the constituent monomers of the block copolymers and polymers will be selected from the following monomers: at least one vinylic, vinylidene, diene, olefinic, allylic or (meth)acrylic monomer. This monomer is selected more particularly from vinyl aromatic monomers such as styrene or substituted styrenes, notably alpha-methylstyrene, silylated styrenes, acrylic monomers such as acrylic acid or salts thereof, alkyl, cycloalkyl or aryl acrylates such as methyl, ethyl, butyl, ethylhexyl or phenyl acrylate, hydroxyalkyl acrylates such as 2-hydroxyethyl acrylate, ether-alkyl acrylates such as 2-methoxyethyl acrylate, alkoxy- or aryloxy-polyalkylene glycol acrylates such as methoxypolyethylene glycol acrylates, ethoxypolyethylene glycol acrylates, methoxypolypropylene glycol acrylates, methoxy-polyethylene glycol-polypropylene glycol acrylates or blends thereof, aminoalkyl acrylates such as 2-(dimethylamino)ethyl acrylate (DMAEA), fluorinated acrylates, silylated acrylates, phosphorus-containing acrylates such as acrylates of alkylene glycol phosphate, glycidyl acrylates, dicyclopentenyloxyethyl acrylates, methacrylic monomers such as methacrylic acid or salts thereof, alkyl, cycloalkyl, alkenyl or aryl methacrylates such as methyl methacrylate (MMA), lauryl, cyclohexyl, allyl, phenyl or naphthyl methacrylates, hydroxyalkyl methacrylates such as 2-hydroxyethyl methacrylate or 2-hydroxypropyl methacrylate, ether-alkyl methacrylates such as 2-ethoxyethyl methacrylate, alkoxy- or aryloxy-polyalkylene glycol methacrylates such as methoxypolyethylene glycol methacrylates, ethoxypolyethylene glycol methacrylates, methoxypolypropylene glycol methacrylates, methoxy-polyethylene glycol-polypropylene glycol methacrylates or blends thereof, aminoalkyl methacrylates such as 2-(dimethylamino)ethyl methacrylate (DMAEMA), fluorinated methacrylates such as 2,2,2-trifluoroethyl methacrylate, silylated methacrylates such as 3-methacryloylpropyltrimethylsilane, phosphorus-containing methacrylates such as methacrylates of alkylene glycol phosphate, hydroxy-ethylimidazolidone methacrylate, hydroxy-ethylimidazolidinone methacrylate, 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamido-propyltrimethyl ammonium chloride (MAPTAC), glycidyl methacrylates, dicyclopentenyloxyethyl methacrylates, itaconic acid, maleic acid or salts thereof, maleic anhydride, alkyl or alkoxy- or aryloxy-polyalkylene glycol maleates or hemimaleates, vinylpyridine, vinylpyrrolidinone, (alkoxy)poly(alkylene glycol) vinyl ether or divinyl ether, such as methoxy poly(ethylene glycol) vinyl ether, poly(ethylene glycol) divinyl ether, olefinic monomers, among which we may mention ethylene, butene, hexene and 1-octene, diene monomers including butadiene, isoprene as well as fluorinated olefinic monomers, and vinylidene monomers, among which we may mention vinylidene fluoride, alone or mixed with at least two aforementioned monomers.

Preferably the block copolymers consist of a block copolymer in which one of the blocks comprises a styrene monomer and the other block comprises a methacrylic monomer; more preferably, the block copolymers consist of a block copolymer in which one of the blocks comprises styrene and the other block comprises methyl methacrylate.

The polymers preferably comprise a styrene monomer or methacrylic monomer; more preferably, the polymers comprise styrene or methyl methacrylate. In a preferred embodiment of the invention, the polymers consist of styrene.

In a preferred embodiment of the invention, for synthesis of the block copolymers and polymers, a method of anionic polymerization in a nonpolar solvent, preferably toluene, will be used, as described in patent EP0749987, employing a micro-mixer. Monomers selected from the following entities will be preferred: at least one vinylic, vinylidene, diene, olefinic, allylic or (meth)acrylic monomer. These monomers are selected more particularly from the vinyl aromatic monomers such as styrene or substituted styrenes, notably alpha-methylstyrene, silylated styrenes, acrylic monomers such as alkyl, cycloalkyl or aryl acrylates such as methyl, ethyl, butyl, ethylhexyl or phenyl acrylate, ether-alkyl acrylates such as 2-methoxyethyl acrylate, alkoxy- or aryloxy-polyalkylene glycol acrylates such as methoxypolyethylene glycol acrylates, ethoxypolyethylene glycol acrylates, methoxypolypropylene glycol acrylates, methoxypolyethylene glycol-polypropylene glycol acrylates or blends thereof, aminoalkyl acrylates such as 2-(dimethylamino)ethyl acrylate (DMAEA), fluorinated acrylates, silylated acrylates, phosphorus-containing acrylates such as acrylates of alkylene glycol phosphate, glycidyl acrylates, dicyclopentenyloxyethyl acrylates, alkyl, cycloalkyl, alkenyl or aryl methacrylates such as methyl methacrylate (MMA), lauryl, cyclohexyl, allyl, phenyl or naphthyl, ether-alkyl methacrylates such as 2-ethoxyethyl methacrylate, alkoxy- or aryloxy-polyalkylene glycol methacrylates such as methoxypolyethylene glycol methacrylates, ethoxypolyethylene glycol methacrylates, methoxypolypropylene glycol methacrylates, methoxy-polyethylene glycol-polypropylene glycol methacrylates or blends thereof, aminoalkyl methacrylates such as 2-(dimethylamino)ethyl methacrylate (DMAEMA), fluorinated methacrylates such as 2,2,2-trifluoroethyl methacrylate, silylated methacrylates such as 3-methacryloylpropyltrimethylsilane, phosphorus-containing methacrylates such as methacrylates of alkylene glycol phosphate, hydroxy-ethylimidazolidone methacrylate, hydroxy-ethylimidazolidinone methacrylate, 2-(2-oxo-1-imidazolidinyl)ethyl methacrylate, acrylonitrile, acrylamide or substituted acrylamides, 4-acryloylmorpholine, N-methylolacrylamide, methacrylamide or substituted methacrylamides, N-methylolmethacrylamide, methacrylamido-propyltrimethyl ammonium chloride (MAPTAC), glycidyl methacrylates, dicyclopentenyloxyethyl acrylates, maleic anhydride, alkyl or alkoxy- or aryloxy-polyalkylene glycol maleates or hemimaleates, vinylpyridine, vinylpyrrolidinone, (alkoxy)poly(alkylene glycol) vinyl ether or divinyl ether, such as methoxy poly(ethylene glycol) vinyl ether, poly(ethylene glycol) divinyl ether, olefinic monomers, among which we may mention ethylene, butene, hexene and 1-octene, diene monomers including butadiene, isoprene as well as fluorinated olefinic monomers, and the vinylidene monomers, among which we may mention vinylidene fluoride, lactones, lactides, glycolides, cyclic carbonates, siloxanes, if necessary protected so as to be compatible with the methods of anionic polymerization, alone or mixed with at least two aforementioned monomers.

According to an alternative embodiment of synthesis, the block copolymers are prepared by anionic polymerization and the polymers will be prepared by controlled radical polymerization.

The block copolymers used in the invention each have the following characteristics:

A number-average molecular weight between 500 g/mol and 500000 g/mol and preferably between 20000 g/mol and 150000 g/mol, and a dispersity index between 1 and 3 and preferably between 1 and 2.

The polymers used in the invention each have the following characteristics:

A number-average molecular weight between 500 g/mol and 500000 g/mol and preferably between 20000 g/mol and 150000 g/mol, and a dispersity index below 3.

The weight ratios of block copolymers to polymers will be between 99/1 and 1/99, preferably between 97/03 and 03/97, more preferably between 97/03 and 55/45 and ideally between 95/05 and 60/40.

In the preferred embodiment of the invention using a block copolymer mixed with a polymer, the ratio of the number-average molecular weights of the polymer to the block copolymer is between 0.2 and 4, preferably between 1 and 3, and more preferably between 1 and 2.

The invention relates in particular to the use of the method according to the invention for making lithography masks or films, as well as the masks and films obtained.

In the case of lithography, however, the structuring required (for example, generation of domains perpendicular to the surface) requires preparation of the surface on which the polymer blend is deposited, in order to control the surface energy. Among the known possibilities, a random copolymer is deposited on the surface, the monomers of which may be completely or partly identical to those used in the block copolymer that is to be deposited. In a pioneering article Mansky et al. (Science, Vol. 275 pages 1458-1460, 1997) give a good description of this technology, which is now familiar to a person skilled in the art.

Among the preferred surfaces we may mention surfaces consisting of silicon, the silicon having a layer of native or thermal oxide, germanium, platinum, tungsten, gold, titanium nitrides, graphenes, BARC (Bottom Anti-Reflective Coating) or any other anti-reflective layer used in lithography.

Once the surface has been prepared, a solution of the blend of block copolymers is deposited and then the solvent is evaporated by techniques known by a person skilled in the art, for example the “spin-coating”, “doctor blade” “knife system”, “slot die system” techniques, but any other technique may be used, such as dry deposition, i.e. without prior dissolution.

Next, a thermal treatment or solvent vapour treatment (annealing) is carried out, or a combination of both treatments, or any other treatment known by a person skilled in the art that allows the blend of block copolymers to be organized correctly (establishment of nanostructuring).

The surfaces may be called “free” (surface that is flat and homogeneous both topographically and chemically) or may have “pattern” guide structures of the block copolymer, whether this guiding is of the chemical guiding type (called “guiding by chemistry-epitaxy”) or physical/topographic guiding (called “guiding by graphoepitaxy”).

The following examples illustrate but do not limit the scope of the invention:

These block copolymers are PS-b-PMMA copolymers prepared according to a protocol described in EP0749987, EP0749987 and EP0524054, with recovery of the block copolymer in question by precipitation in a non-solvent at the end of synthesis, such as an 80/20 volume mixture of cyclohexane/heptane. The polymers are homopolymers of PS prepared according to the same protocol, the second step (PMMA) not being carried out; the living PS is deactivated by adding a methanol/hydrochloric acid mixture or any other proton donor.

They have the following characteristics:

| Product | | MW | | | Copolymer composition | | | | |
|---|---|---|---|---|---|---|---|---|---|
| Product | | Mn PS | Mn PMMA | Mn copo | | wt % | wt % | % homo | % homo |
| name | Nature | (kg/mol)^{a} | (kg/mol)* | (kg/mol)* | Dispersity^{a} | PS^{b} | PMMA^{b} | PS^{c} | PMMA^{c} |
| 13P13CG3 | PS-PMMA | 40.3 | 20.9 | 61.2 | 1.11 | 65.9 | 34.1 | 0.8 | 3.7 |
| 13P16CL2 | PS-PMMA | 38.6 | 17.6 | 56.2 | 1.06 | 68.7 | 31.3 | 1.0 | 1.0 |
| 12CV07 | PS | 9.2 | / | / | / | / | / | / | / |
| 13P16PS | PS | 38.6 | / | / | / | / | / | / | / |
| 13P286PS | PS | 94.6 | / | / | / | / | / | / | / |
| 13P13PS | PS | 40.3 | / | / | / | / | / | / | / |
| 13P07PS | PS | 111.7 | / | / | / | / | / | / | / |

^{a}by SEC with PS standards
^{b}by ¹H NMR
^{c}by LAC with PS and PMMA standards
*by calculation using the PS MW determined by SEC and the composition determined by NMR

The molecular weights and the dispersity corresponding to the ratio of the weight-average molecular weight (Mw) to the number-average molecular weight (Mn) are obtained by SEC (Size Exclusion Chromatography), using two AGILENT 3 μm ResiPore columns in series, in a medium of THF stabilized with BHT at a flow rate of 1 mL/min at 40° C. with samples concentrated to 1 g/L, calibrated beforehand with calibrated samples of polystyrene using an Easical PS-2 prepared pack. The PS/PMMA weight ratio is obtained by proton NMR on a Bruker 400 instrument, by integrating the 5 aromatic protons of PS and the 3 protons of the methoxy of PMMA.

The invention can also be carried out using other block copolymers and other PS of some other origin.

### Example 1

Deposition of the solutions on a surface is carried out as follows:

Surface preparation, grafting on SiO₂:

Silicon plates (crystallographic orientation {100}) are cut manually into 3×4 cm pieces and cleaned by treatment with H₂SO₄/H₂O₂ 2:1 (v:v)) for 15 minutes, then rinsed with deionized water, and dried under a nitrogen stream just before functionalization. The rest of the procedure is as described by Mansky et al. (Science, 1997, 1458), with Just one modification (annealing is carried out under ambient atmosphere and not under vacuum). A PS-r-PMMA random copolymer with molecular weight of 10 000 g/mol and PS/PMMA ratio of 74/26, prepared by controlled radical polymerization using NMP technology, according to a protocol described in WO20121400383 example 1 and example 2 (copolymer 10), for neutralizing the surface, is dissolved in toluene to obtain solutions at 1.5 wt %. This solution is dispensed manually on a freshly cleaned wafer, and then spread by spin-coating at 700 rev/min to obtain a film with a thickness of about 40 nm. The substrate is then simply deposited on a heating plate, previously heated to the desired temperature, under ambient atmosphere for a variable time. The substrate is then washed by sonication in several baths of toluene for a few minutes in order to remove the ungrafted polymer from the surface, and then dried under a nitrogen stream. It should be noted that throughout this procedure, it is equally possible to use PGMEA instead of toluene.

Any other copolymer can be used, typically a P(MMA-co-styrene) random copolymer as used, by Mansky, provided a composition of styrene and MMA suitable for neutralization is selected.

Next, the solution of block copolymer or mixture of block copolymers and polymer (1 wt % in propylene glycol-monomethyl ether acetate) is deposited by “spin-coating” on the previously treated surface and then thermal annealing is carried out at 230° C. for at least 5 minutes in order to evaporate the solvent and give the morphology time to become established.

This is carried out in such a way that the thickness of the film of block copolymers or blend of block copolymers is 40 nm. Typically, the solution to be deposited (1% in PGMEA) is deposited on a 2.7×2.7 cm specimen by spin-coating at 700 rev/min.

The measurements of film thickness are performed on Prometrix UV1280 ellipsometer.

The following blends are considered:

Samples: 13P16CL2, 13P13CG3

All the block copolymer/homopolymer blends have, a weight ratio of 9/1.

| Specimen | Pure BCP | Defectiveness (%) | MhPS/MPS BCP ratio | Mn hPS (g/mol) | hPS used |
|---|---|---|---|---|---|
| 1 | 13P16C-L2 | 6.970397794 | 0 | | |
| 2 | 13P16C-L2 | 6.307980873 | 0.248704663 | 9600 | 12CV07 |
| 3 | 13P16C-L2 | 5.315446905 | 1 | 38600 | 13P16PS |
| 4 | 13P16C-L2 | 5.151099198 | 1.816062176 | 70100 | 13P286PS |
| 5 | 13P16C-L2 | 6.006186334 | 3.056994819 | 118000 | 13P07PS |
| 6 | 13P13C-G3 | 9.914072757 | 0 | | |
| 7 | 13P13C-G3 | 9.527086753 | 0.235872236 | 9600 | 12CV07PS |
| 8 | 13P13C-G3 | 8.381152002 | 1 | 40300 | 13P13PS |
| 9 | 13P13C-G3 | 8.080411818 | 1.722358722 | 70100 | 13P286PS |
| 10 | 13P13C-G3 | 8.874533893 | 2.899262899 | 118000 | 13P07PS |

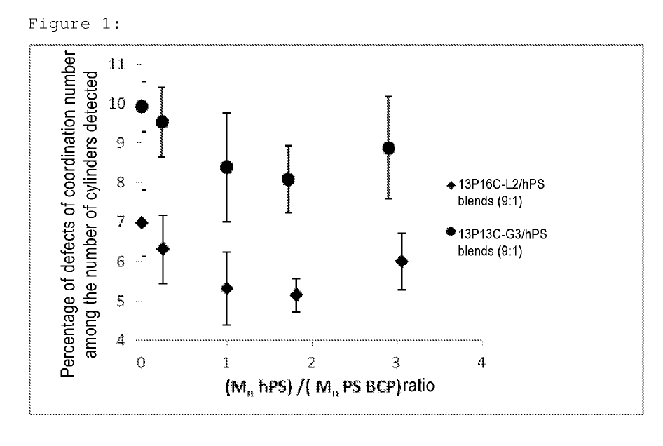

FIG. 1 shows the percentage of defects of coordination number among the number of cylinders detected as a function of the ratio of the number-average molecular weights of the polymer to the number-average molecular weight of the block copolymer. It can be seen that the blends of block copolymers with polymers have fewer defects of coordination number and that an optimum is observed for ratios of number-average molecular weights of the polymer to the number-average molecular weight of the block copolymer between 1 and 2.

1. A method for controlling the level of defects of orientation, of coordination number or of distance on large single-crystal surfaces with improvement of the CDU of a nanostructured assembly in the form of a film of block copolymer/polymer blend, said blend comprising n block copolymers and m polymers that comprise at least one monomer identical to those present in one or other block of the block copolymers, comprising the following steps:
forming a mixture comprising block copolymers and polymers in a solvent;
depositing the mixture on a surface; and
annealing the mixture.

2. A method according to claim 1, wherein n is equal to 1 and m is equal to 1.

3. A method according to claim 2, wherein the block copolymer is a diblock copolymer.

4. A method according to claim 2, wherein the polymer is a random copolymer.

5. A method according to claim 2, wherein the polymer is a copolymer comprising methyl methacrylate.

6. A method according to claim 2, wherein the polymer is a copolymer comprising styrene.

7. A method according to claim 6, wherein the copolymer is a PS homopolymer.

8. A method according to claim 3, wherein the block copolymers comprise a methacrylic monomer in one of the blocks and a styrene monomer in the other block.

9. A method according to claim 8, wherein the block copolymer is a PS-PMMA copolymer.

10. A method according to claim 1, wherein the number-average molecular weights of the block copolymers are between 500 and 500000 g/mol.

11. A method according to claim 1, wherein the weight ratio of block copolymers to polymers is between 99/1 and 1/99.

12. A method according to claim 1, wherein the block copolymers are prepared by controlled radical polymerization.

13. A method according to claim 1, wherein the polymers are prepared by controlled radical polymerization.

14. A method according to claim 12, wherein nitroxide-controlled radical polymerization is carried out.

15. A method according to claim 14, wherein radical polymerization is carried out, controlled by N-tert-butyl-1-diethylphosphono-2,2-dimethylpropyl nitroxide.

16. A method according to claim 1, wherein the block copolymers and the polymers are prepared by anionic polymerization.

17. A method according to claim 1, wherein the block copolymers are prepared by anionic polymerization and the polymers are prepared by controlled radical polymerization.

18. A method according to claim 1, wherein the film thickness is greater than or equal to 40 nm.

19. A method according to claim 2, wherein the ratio of the number-average molecular weights of the polymer to the block copolymer is between 0.2 and 4.

20. A method according to claim 1, wherein the surface is free.

21. A method according to claim 1, wherein the surface is guided.

22. A method according to claim 1, wherein the method is used to produce a product selected from the group consisting of lithography masks or films.

23. A lithography mask or film obtained according to claim 22.
